(19) United States
(12) Patent Application Publication
(10) Pub. No.: US 2010/0270600 A1
(43) Pub. Date: Oct. 28, 2010

(54) SEMICONDUCTOR INTEGRATED CIRCUIT DEVICE AND METHOD OF DESIGNING THE SAME

(75) Inventors: Takashi Inukai, Yokohama-Shi (JP); Koichi Kinoshita, Yokohama-Shi (JP); Masato Kanie, Yokohama-Shi (JP)

Correspondence Address: SPRINKLE IP LAW GROUP, 1301 W. 25TH STREET, SUITE 408, AUSTIN, TX, 78705, US

(73) Assignee: Kabushiki Kaisha Toshiba, Tokyo (JP)

(21) Appl. No.: 12/728,913

(22) Filed: Mar. 22, 2010

(30) Foreign Application Priority Data
Apr. 27, 2009 (JP) 2009-107604

(51) Int. Cl. H01L 29/78; G06F 17/50

(52) U.S. Cl. 257/288; 716/2; 716/6; 257/E29.255

(57) ABSTRACT

A method of designing a semiconductor integrated circuit device includes: arranging standard cells constituting a MISFET; analyzing an operation timing and/or power consumption of the arranged standard cells; identifying one of the standard cells that is desired to have improved properties as a cell of interest based on the obtained analysis result; optimizing an arrangement and a shape of blank areas around the cell of interest taking into account an influence of a well proximity effect; and replacing the blank area and/or the cell of interest with a WPE-reduced or WPE-enhancing cell.

### CROSS REFERENCE TO RELATED APPLICATION

This application claims benefit of priority under 35 USC §119 to Japanese patent application No. 2009-107604, filed on Apr. 27, 2009, the contents of which are incorporated by reference herein.

### BACKGROUND

1. Field of the Invention

The present invention relates to a semiconductor integrated circuit device and a method of designing the same.

2. Related Background Art

Recently, due to a desire for lowering power consumption, the power supply voltage of semiconductor devices has been reduced in general, which has raised a problem of increasing off-leakage currents. Thus, a method of solving such a problem is desired in designing a layout of the semiconductor integrated circuits.

Further, as for a semiconductor integrated circuit device including metal insulator semiconductor field effect transistors (MISFETs), the problem of fluctuations in characteristics depending on the layout thereof is exposed according to the development in fine processing.

More specifically, due to a well proximity effect (hereinafter abbreviated as “WPE” simply) by which a threshold value Vth at which transistors are turned on/off fluctuates depending on a distance from a neighboring well boundary, a problem occurs in that as the distance from the well boundary decreases, the threshold value Vth increases and an off-leakage current reduces but a margin of operation timing decreases.

Since there is a relationship of trade-off between the off-leakage current and the margin of operation timing, if the dependency can be utilized appropriately in suitable places, it is possible to reduce the off-leakage current without deteriorating an operation speed of the semiconductor integrated circuits. Specifically, a larger influence by the WPE is preferable for a MISFET arranged along a circuit pass with a larger margin of operation timing, and a smaller influence by the WPE is preferable for a MISFET with a smaller margin of operation timing.

There is known a method of reducing an off-leakage current of a semiconductor integrated circuit without deteriorating its operation speed by manufacturing MISFETs of different Vth values. However, this method needs to have the same number of Vth control processes as the number of the Vth values, thus increasing costs for manufacturing.

In designing of the layout of a semiconductor integrated circuit of a cell standard system, standard cells are disposed based on a logical circuit diagram and, subsequently, interconnections are arranged and then filler cells are disposed in a blank area where none of the standard cells was disposed (for the layout of the filler cells, see Japanese Patent Laid Open Publication No. 2007-027290).

The WPE is generated by the filler cells and exerts an influence on the characteristics of the MISFETs arranged around the filler cell.

### SUMMARY

In accordance with a first aspect of the invention, there is provided a method of designing a semiconductor integrated circuit device, said method comprising:

arranging standard cells which constitute a MISFET;

analyzing, by using a simulator, an operation timing and/or power consumption of the arranged standard cells and obtaining a result of the analysis;

identifying one of the standard cells that is desired to have improved properties as a cell of interest based on the obtained analysis result;

optimizing an arrangement and/or a shape of blank areas around the cell of interest taking into account an influence of a well proximity effect; and

replacing the blank area and/or the cell of interest with a cell having influence of well proximity effect.

In accordance with a second aspect of the invention, there is provided a semiconductor integrated circuit device comprising:

a first well of a first conductivity type semiconductor arranged on a substrate;

a second well of a second conductivity type semiconductor arranged on the substrate adjacent to the first well; and

a third well of the first conductivity type semiconductor arranged on the substrate adjacent to the second well in such a manner that the second well is sandwiched between the first well and the third well,

wherein a MISFET of the first conductivity type is arranged in a first region of the second well, and

assuming that a carrier conduction direction in the MISFET is a first direction and that a direction perpendicular to the first direction is a second direction, a length of the first region in the second well in the second direction is smaller than a length of a second region adjacent to the first region in the first direction and a portion of the third well facing the first region protrudes toward the second well.

### BRIEF DESCRIPTION OF THE DRAWINGS

FIG. 1 is a block diagram showing an outlined constitution of a designing apparatus for a semiconductor integrated circuit device according to an embodiment of the present invention;

FIG. 2 is a flowchart showing outlined processes of a method of designing a semiconductor integrated circuit device according to an embodiment of the present invention;

FIG. 3 is an explanatory diagram of the process of optimizing a blank area;

FIG. 4 is a diagram showing a layout obtained by optimizing the blank area and performing replacement by a WPE-enhancing cell;

FIGS. 5 and 6 are explanatory diagrams of the process of optimizing the blank area;

FIG. 7 is a diagram showing a layout obtained by optimizing the blank area and performing replacement by a WPE-reduced cell;

FIG. 8 is another explanatory diagram of the process of optimizing the blank area;

FIG. 9 is a schematic diagram of a specific example of layout variations of the WPE-reduced cell;

FIG. 10 is an explanatory diagram of the process of optimizing blank areas, the process of performing replacement by the WPE-reduced cell; and

FIGS. 11A to 11D are explanatory diagrams of the process of optimizing blank areas, the process of performing replacement by the WPE-reduced cell; and

FIGS. 12A to 12D are explanatory diagrams of the process of optimizing blank areas, the process of performing replacement by the WPE-enhancing cell, and the process of inserting the filler cell.

### DETAILED DESCRIPTION

Hereafter, some of embodiments of the present invention will be described with reference to the drawings. In the drawings, identical reference numerals are given to identical components, and repetitive description on the identical components will be described only in case of necessity. It is to be noted that in the following description, the size of a standard cell in a carrier conduction direction in a MOSFET is referred to as a width of the standard cell and the size of a filler cell in the same direction is referred to as a width of the filler cell. Further, a direction perpendicular to the carrier conduction direction in the MOSFET, that is, a gate direction is referred to as a height direction. The size of the standard cell in the height direction is referred to as a height of the standard cell, and the size of a filler cell in the height direction is referred to as a height of the filler cell.

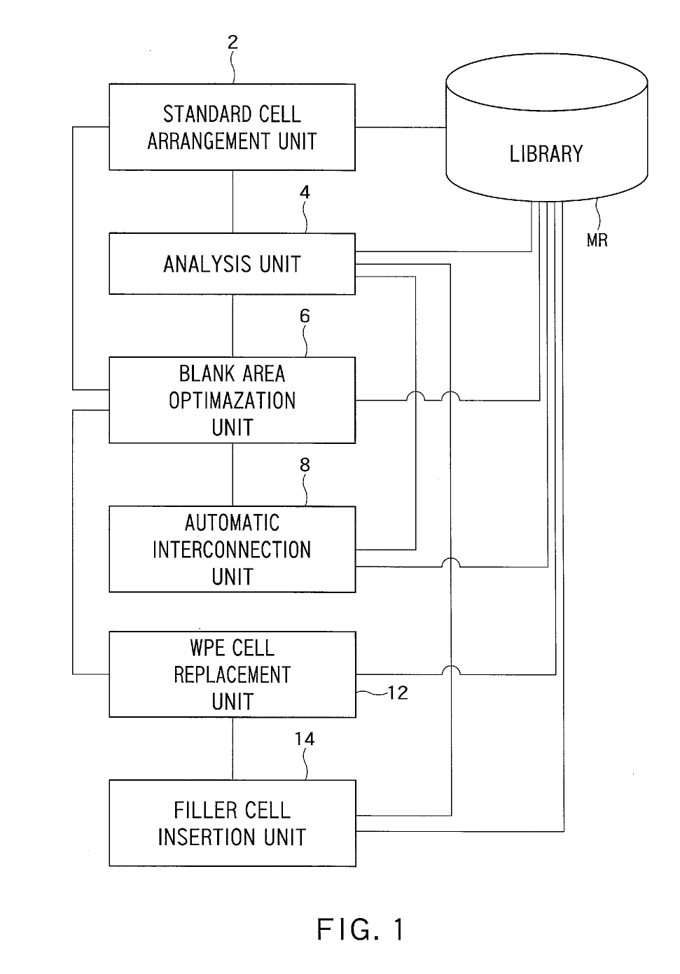

FIG. 1 is a block diagram showing the outlined constitution of a designing apparatus for a semiconductor integrated circuit device according to one embodiment of the present invention. The designing apparatus shown in FIG. 1 includes a standard cell arrangement unit 2, analysis unit 4, a blank area optimization unit 6, an automatic interconnection unit 8, a layout changing unit 12, and a filler cell insertion unit 14, and a library MR. These units are processed individually and properly read out information from the library VR. The library MR contains the information of standard sells and filler cells, and is connected to the analysis unit 4 and filler sell insertion unit 14. Thus, these units 4 and 14 can read the information of standard sells and filler cells, respectively. The standard cell arrangement unit 2 is connected to the analysis unit 4, reads out information of the standard cells from the library MR via the analysis unit 4, creates a temporary circuit layout, and supplies the temporary circuit layout to the analysis unit 4. The analysis unit 4 contains a simulator and is connected to the blank area optimization unit 6, the automatic interconnection unit 8, and the filler cell insertion unit 14, and analyzes, by simulation, operation timings, power consumption, etc. of the circuit layout supplied from those units. The blank area optimization unit 6 is connected to the analysis unit 4 as well as to the standard cell arrangement unit 2, the automatic interconnection unit 8, and the layout changing unit 12, and optimizes blank areas in a layout based on a result of analysis from the analysis unit 4. The automatic interconnection unit 8 performs automatic interconnection (which can be referred as “routing”) processing on the layout in which the blank areas are optimized. The layout changing unit 12 is connected also to the filler cell insertion unit 14, further changes the layout by replacing the blank areas or both of the blank areas and a standard cell of interest, with a WPE-reduced cell or a WPE-enhancing cell and supply it to the filler cell insertion unit 14. The cell of interest, the WPE-reduced cell, and the WPE-enhancing cell will be described below. The filler cell insertion unit 14 reads the information of the filler cells out of the library MR, and inserts filler cells into the blank areas in the layout changed by the layout changing unit 12.

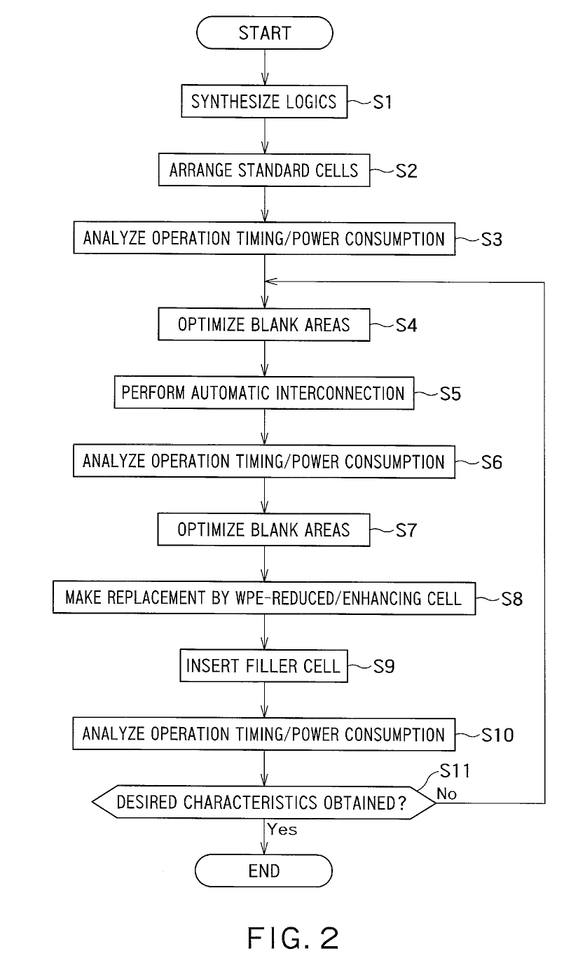

Next, a description will be given of a method of designing a semiconductor integrated circuit device by using the designing apparatus for a semiconductor integrated circuit device of FIG. 1, with reference to FIG. 2.

FIG. 2 is a flowchart showing an outlined procedure which is used in the method of designing the semiconductor integrated circuit device according to an embodiment of the present invention. One of the characteristic features of the present embodiment is that the designing method improves performance of the integrated circuit device by designing it with use of WPE phenomena in a positive manner as shown in steps S4 and S7 to 9 of FIG. 2. They will be described below in sequence.

First, a dedicated tool (not shown) generates a gate level netlist based on circuit operation specifications written in the hardware description language and feeds the gate level netlist to the standard cell arrangement unit 2 (step S1). The standard cell arrangement unit 2 reads standard cells from the library MR via the analysis unit 4, arranges the cells, and thus provides a first temporary layout (step S2).

Next, the analysis unit 4 analyzes operation timings and power consumption of the obtained first temporary layout, and checks for a margin of the operation timings and necessary power consumption levels for each of the standard cells (step S3).

Subsequently, the blank area optimization unit 6 identifies one cell of the standard cells that has a margin of the operation timing as a cell of interest, based on the result of the analysis. The blank area optimization unit 6 further optimizes the blank areas (step S4) by changing a shape and/or a position of blank areas around the identified cell of interest as to enhance its WPE, thus provides a second temporary layout. It is to be noted that the “cell of interest” refers to a cell to which attention is paid from an operator because better properties are desired; in step 4 of the present embodiment, attention is paid from the viewpoint that the cell is desired to have a smaller off-leakage current.

Next, the automatic interconnection unit 8 performs automatic interconnection processing on the second temporary layout in which the blank areas have been thus optimized (step S5) and supplies a resultant layout obtained by this processing to the analysis unit 4. The analysis unit 4 further analyzes the operation timings and power consumption of the layout obtained as a result of the interconnection processing, and checks for the margin of the operation timings and the necessary power consumption levels for each of the standard cells again (step S6).

Subsequently, the blank area optimization unit 6, based on a result of the second analysis, identifies one cell of the standard cells that is critical in operation timing or desired to have higher driving capability as a cell of interest from a viewpoint of improvements in operation speed and driving capability. The blank area optimization unit 6 further optimizes the blank areas (step S7) by changing the shape and/or the position of blank areas around the identified cell of interest so as to reduce its WPE. The result of the further optimization is supplied to the layout changing unit 12. The layout changing unit 12 then identifies at least a part of the optimized blank areas on which the WPE can be utilized, and replaces the identified blank area, or both of the identified blank area and the standard cells of interest, with the WPE-reduced cell or the WPE-enhancing cell (step S8). It is to be noted that the WPE-reduced cell refers to a cell in which the operation speed and the driving capability are improved by reducing its WPE, and the WPE-enhancing cell refers to a cell which is used to reduce the off-leakage current of a cell of interest by enhancing the WPE of the cell of interest.

The filler cell insertion unit 14 inserts filler cells into the blank areas in the layout which is changed by replacement by the WPE-reduced cell or the WPE-enhancing cell (step S9).

Furthermore, the analysis unit 4 performs the third analysis on the operation timing and the power consumption of the circuit arrangement (which can be referred as “placement”) for which the insertion processing of the filler cells (step S10) is completed. The designing apparatus in FIG. 1 then repeats the processes from step S4 to step S10 until desired properties of the whole circuit are obtained (step S11). When the desired properties of the whole circuit are obtained, The designing apparatus ends the circuit design.

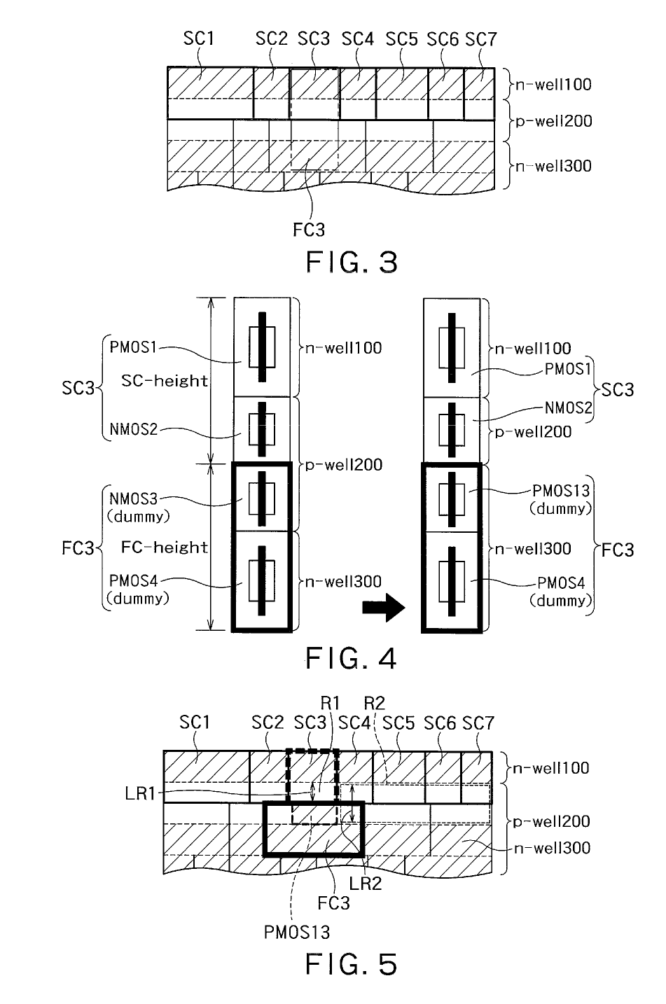

Next, a description will be given more specifically of the details of steps S4 and S8 of FIG. 2 with reference to FIGS. 3 to 5.

In a layout shown in FIG. 3, an n-well 100, a p-well 200, and an n-well 300 are formed sequentially downward from the top of the sheet in such a manner that they may each extend horizontally on the sheet. Those wells are to be formed in a substrate (not shown) of an actual semiconductor device. The substrate may be, besides a semiconductor substrate, a ceramic substrate or a glass substrate. It is to be noted that in FIG. 3, the n-wells are hatched so that they may be distinguished from the p-well easily. This way of hatching also applies to FIGS. 5, 6, 8, and 10. Further, in FIG. 3, standard cells SC1 to SC7 are disposed each of which is composed of a pair of a p-type Metal Oxide Semiconductor Field Effect Transistor (PMOS) and an n-type Metal Oxide Semiconductor Field Effect Transistor (NMOS). Additionally, a filler cell FC3 composed of a pair of a PMOS and an NMOS is temporarily disposed adjacent to the standard cell SC at the lower part of the sheet. The filler cell FC3 is a dummy cell constituted of a dummy MOSFET that does not function as a transistor. The dummy cell is disposed for a purpose of inhibiting process-wise fluctuations and a purpose of being utilized when changing the circuit; in the present embodiment, it is disposed for the former purpose. A region in FIG. 3 enclosed by an alternate long and short dash line is shown enlarged on the left side of the sheet of FIG. 4. It is to be noted that in FIG. 4, symbol “SC-height” indicates the height of the standard cell and symbol “FC-height”, the height of the dummy cell.

Assume here that it is determined at the process of step S3 that a standard cell SC3 has a margin of operation timing. In this case, it is accepted for the transistors of the standard cell SC3 to have a raised ON/OFF threshold value and a lowered speed. Therefore, since the standard cell SC3 can be expected to have a suppressed off-leakage current, it is set as a cell of interest, in the process of step S8, a dummy element NMOS3 in the filler cell FC3 adjacent to an NMOS2 of the standard cell SC3 is replaced with a dummy element PMOS13 as shown on the right side of the sheet of FIG. 4. Resultantly, as shown in FIG. 5, the p-well 200 is shaped so that a region R1 in which the NMOS2 is formed may cave in by the PMOS13 formed in it, so that a height-directional size LR1 of the region R1 is smaller than a height-directional size LR2 of a region which is horizontally adjacent on the sheet, for example, a rightward adjacent region R2. Correspondingly, the n-well 300 is shaped so that its portion that faces the region R1 may protrude into the p-well 200 toward the standard cell SC3 and its well boundary originally positioned to almost the middle of the filler cell FC3 may come near a boundary between the standard cell SC3 and the filler cell FC3, thus enhancing the WPE on the NMOS2 in the standard cell SC3. As a result, the ON/OFF threshold value of the NMOS2 in the standard cell SC3 rises, and its leakage current is reduced. In the present embodiment, the regions R1 and R2 correspond to first and second regions, for example.

In such a manner, in the present embodiment, by replacing the dummy element NMOS3 adjacent to the NMOS2 of the standard cell SC3 with the PMOS13 having an inverted conductivity type rather than replacing the NMOS2 itself, it is possible to reduce a leakage current in the NMOS2 of the standard cell SC3. In contrast to the conventional techniques by which, for example, the WPE has been suppressed to secure the margin of timing, the present embodiment conversely utilizes the WPE positively, thereby enabling the reduction of the leakage current. It is to be noted that the PMOS13 in the filler cell corresponds to a “WPE-enhancing cell” which is used to enhance the WPE.

Conventionally, in the case of sequentially disposing the standard cells PMOS1 and NMOS2 and the filler cells NMOS3 and PMOS4 downward from the top of the sheet of FIG. 4 in such a manner that the standard cells and the filler cells may be adjacent to each other in the height direction as shown on the left side in FIG. 4, the MOSFETs having the same conductivity type have been disposed adjacent to each other. In contrast, in the present embodiment, an FET-type semiconductor integrated circuit device is provided in which the standard cells PMOS1 and NMOS2 and the filler cells PMOS13 and PMOS4 are sequentially disposed downward from the top of the sheet so that its off-leakage current may be suppressed as shown, for example, on the right side in FIG. 4. In the present embodiment, the n-well 100, the p-well 200, and the n-well 300 correspond to, for example, first through third wells respectively. Further, the standard cell NMOS2 corresponds to, for example, a MISFET having the first conductivity type.

It is to be noted that although FIGS. 3-5 have used an example where some wells in the filler cell have the inverted conductivity type, the present invention is not limited to it and can be applied to a variety of modifications; for example, the n-well and the p-well may both have the inverted conductivity type.

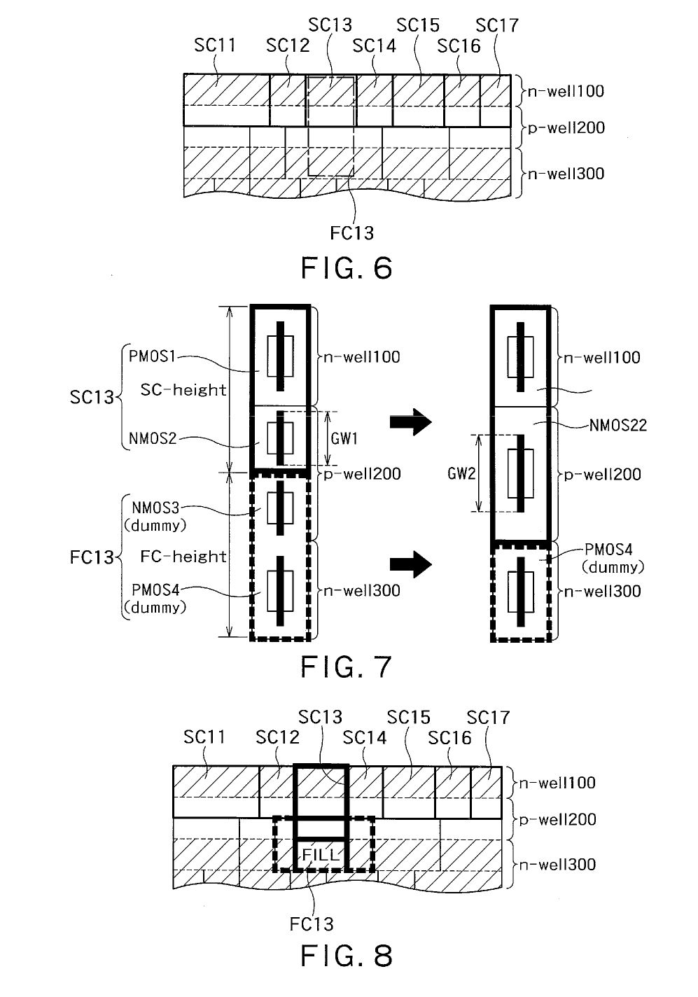

Next, a description will be given more specifically of steps S7 to S9 which provide a characteristic process in the present embodiment, with reference to FIGS. 6 to 12.

In a layout shown in FIG. 6, like FIG. 3, the n-well 100, the p-well 200, and the n-well 300 are formed sequentially downward from the top of the sheet in such a manner that they may each extend horizontally on the sheet, to temporarily dispose the standard cells SC11 to SC17 each of which is composed of a PMOS and an NMOS and also the filler cell FC13 which is similarly composed of a PMOS and an NMOS. Assume here that it is determined at the second analysis process of step S6 that the standard cell SC13 is critical in operation timing or desired to have high driving capability.

If the cell does not have a margin of operation timing and is timing-wise critical or desired to have high driving capability, it is necessary to raise their operation speed by lowering the ON/OFF threshold value of its transistors, or to enhance the driving capability by increasing their sizes. For this purpose, from the viewpoint of preferably improving properties of the operation speed and the driving capability, the standard cell SC13 is set as a cell of interest and, as shown in FIGS. 7 and 8, by performing steps S7 and S8, the dummy NMOS3 in the filler cell FC13 is removed to leave only the dummy PMOS4, then, by taking the blank area obtained by removing the dummy NMOS3 into the region for the NMOS of the standard cell SC13, the size of the transistor NMOS2 of the standard cell SC13 is increased, thereby the NMOS22 is provided. Accordingly, a gate width GW is also increased (GW2 is larger than GW1 in FIG. 7) to improve the driving capability and also, in the standard cell SC13, the boundary between the n-well 100 and the p-well 200 gets away as viewed from a channel region of the NMOS22 as compared to the condition before the replacement, thereby enabling reducing the WPE correspondingly. As a result, the ON/OFF threshold value of the NMOS22 is lowered as compared to that before the replacement, to speed up its operation. It is to be noted that the NMOS22 shown in FIG. 7 corresponds to a “WPE-reduced cell” which is used to reduce the WPE. It is to be noted that although a cell constitution diagram on the left side in FIG. 7 is essentially the same as that on the left side in FIG. 4, it is shown here again for ease of understanding.

In such a manner, in the present embodiment, it is possible to replace a standard cell of interest and a filler cell adjacent to it with a cell having a different height, thereby improving the operation speed and the driving capability of the NMOS in the standard cell SC3.

It is to be noted that although FIGS. 6 to 8 have shown an example where the widths of the standard cell and the filler cell in the carrier conduction direction stay unchanged before and after they are replaced with the WPE-reduced cell, and the relative positional relationship between the standard cell and the filler cell also stay unchanged before and after the replacement. However, the present invention is never limited to the example. In order to obtain desired WPE-reduced effects or WPE-enhancing effects, the widths or the relative positional relationship may change before and after the replacement by the WPE-reduced or WPE-enhancing cell or the cell to be replaced may be subdivided before the replacement. Further, it is also possible to use a filler cell having any shape other than a square.

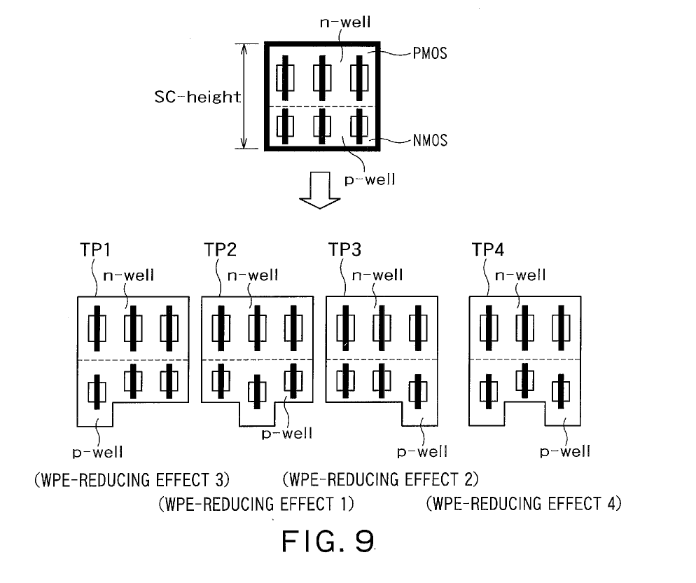

Further, information in which the WPE-reduced or WPE-enhancing degree is digitized (level-coded) can be beforehand added to the standard cell and may be utilized in layout change later. FIG. 9 schematically shows a specific example of such layout variations. In the example shown in FIG. 9, the WPE-reduced effects become more remarkable in ascending order of a pattern TP2 (variations at the midsection), a pattern TP3 (variations on the right side), a pattern TP1 (variations on the left side), and a pattern TP4 (variations on both right and left sides).

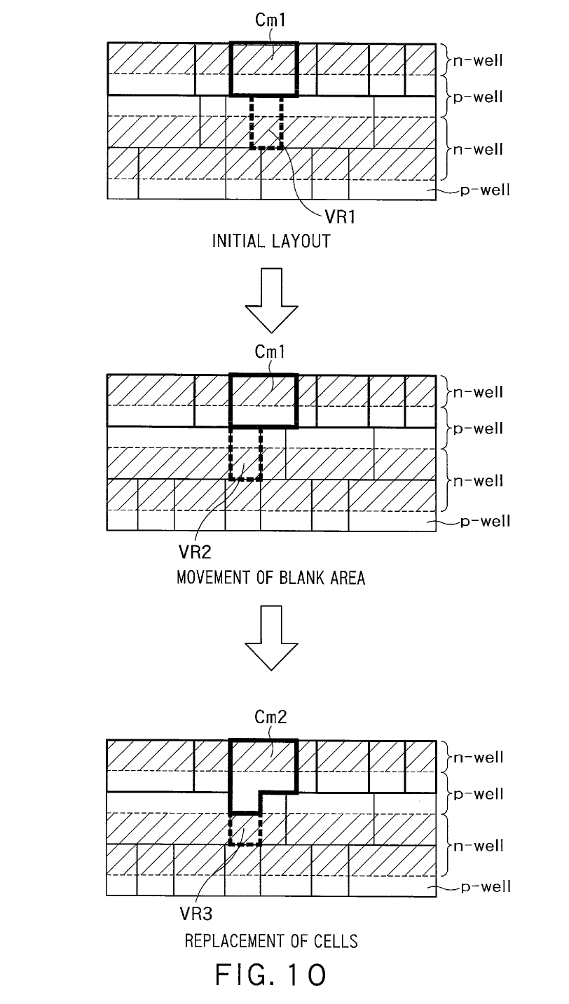

A description will be given here in more detail of an initial layout (first temporary layout) at the process of step S2, the blank area optimization processing (step S7), and the replacement processing of the standard cell by the WPE-reduced/WPE-enhancing cell (step S8), with reference to FIG. 10. An example in FIG. 10 shows the following processes: first, a blank area VR1 contacting the midsection of a cell of interest Cm1 on the lower side is moved leftward in such a manner that the left edge of the blank area VR1 may be aligned to the left edge of the cell of interest Cm1 through the optimization processing, thereby becoming a blank area VR2. Then, the blank area VR2 is downsized to become VR3 by the replacement of the cell of interest by the WPE-reduced cell or the WPE-enhancing cell. At the same time, the size of the cell of interest Cm1 is increased downward on the sheet by the volume corresponding to the difference between the original sizes of VR1 and VR3, thereby becoming a new cell Cm2. Processing of FIG. 10 utilizes, for example, the pattern TP1 in FIG. 9.

A description will be given more specifically of such initial layout, blank area optimization, and replacement thereof by a WPE-reduced/enhancing cell, with reference to an example where the interconnection processing is already conducted.

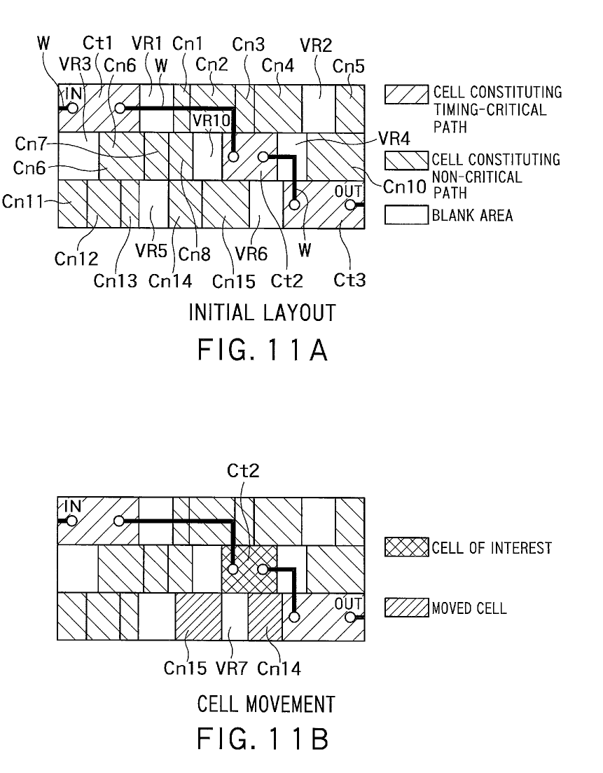

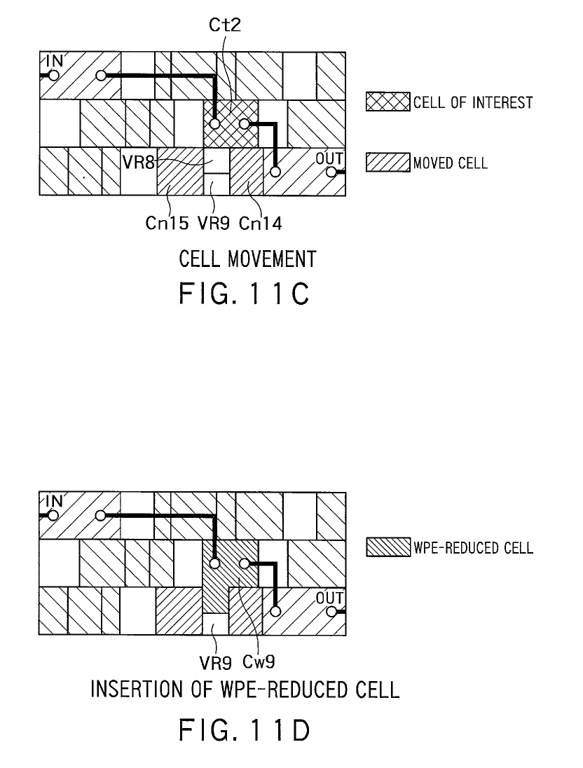

FIGS. 11A to 11D show one example of the case in which an operation timing is optimized. FIG. 11A shows a cell layout after the second analysis (step S6) of an operation timing after the interconnection processing (step S5 in FIG. 2) and of power consumption has ended. As a result of the second analysis, cells Ct1 to Ct3 that constitute a timing-critical path are extracted as a critical cell. The other standard cells Cn1 to Cn8 and Cn10 to Cn15 constitute a non-critical path. It is to be noted that in the figures, symbol W indicates an interconnection, symbol IN indicates an input terminal, and symbol OUT indicates an output terminal.

Next, one of the cells Ct1 to Ct3 of the timing-critical path that gives large effects in improvements of the operation timing if replaced with the WPE-reduced cell is extracted as a cell of interest. In the example shown in FIG. 11B, the cell Ct2 is extracted.

Subsequently, the layout of the cells Cn1 to Cn8 and Cn10 to Cn15 of the non-critical path is changed so as to generate blank areas around the cell Ct2, which is effective in improvements by moving the cells Cn14 and Cn15. In the example shown in FIG. 11B, the cell Cn14 is moved, the cell Cn15 is moved so that the left edge of the blank area VR6 is aligned with the left edge of the Cell of interest Ct2. Thus, the width of the blank area VR6 is changed (narrowed), thereby the blank area VR6 becomes a blank area VR7.

Next, the blank area VR7 is divided into two blank areas VR8 and VR9, as shown in FIG. 11C.

Finally, as shown in FIG. 11D, both of the cell of interest Ct2 and of the blank area VR8 are wholly replaced with a WPE-reduced cell Cw9.

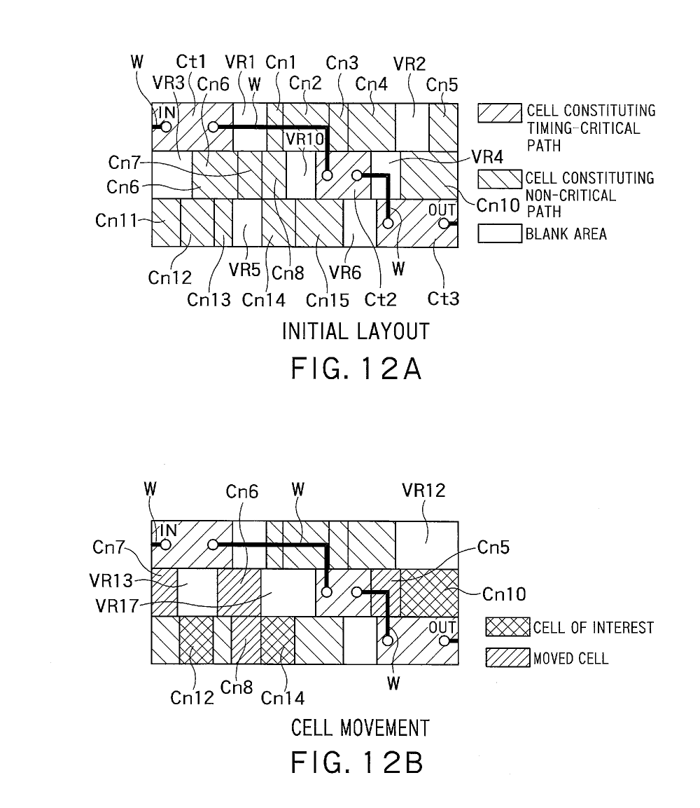

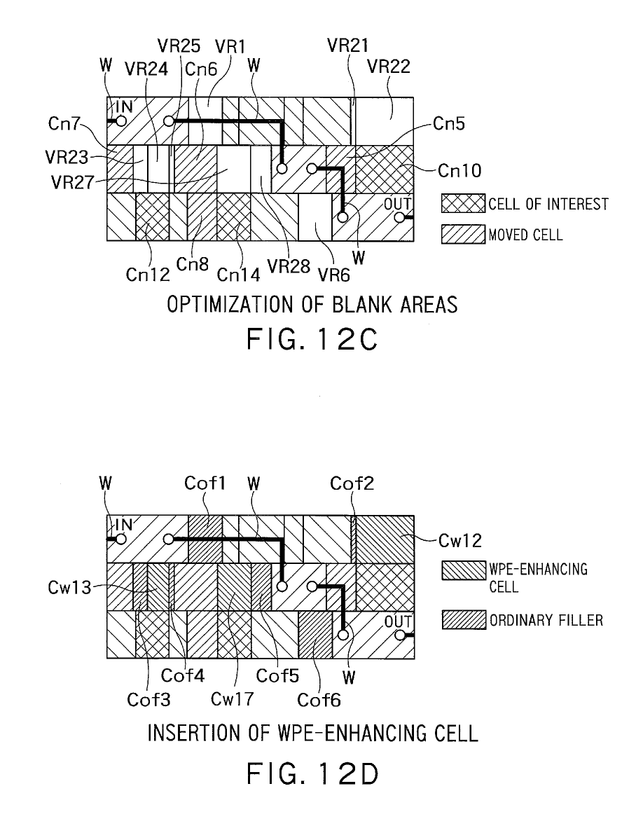

FIGS. 12A to 12D show one example of the case in which a leakage current is reduced. FIG. 12A shows a cell layout after the analysis of the operation timing after the interconnection processing and of power consumption has ended (steps S2 and S3, respectively). FIG. 12A is the same as FIG. 11A, however, is shown here again for ease of explanation.

First, one of the cells Cn1 to Cn15 of the non-critical path is extracted that gives large effects in reduction of leakage currents if the WPE-enhancing cell (see, for example, the filler cell PMOS13 in FIG. 4) is used in its adjacent region. In the example shown in FIG. 12B, the cells Cn10, Cn12, and Cn14 are extracted as cells of interest.

Subsequently, the layout of the original blank areas VR2, VR3, and VR5 and the cells Cn5 to Cn8 of the non-critical path is changed in such a manner that blank areas are generated around the cells Cn10, Cn12, and Cn14, respectively, by moving the cells Cn5-8. As a result, in the example shown in FIG. 12B, the relative position and/or the width of the blank areas VR2, VR3, VR5 and VR10 are changed, thereby these blank areas VR2, VR3, VR5 and VR10 become blank areas VR12, VR13, and VR17 around the cells Cn10, Cn12, and Cn14 on the upper side thereof, respectively.

Next, as shown in FIG. 12C, the blank area VR12 is divided into two blank areas VR21 and VR22, the blank area VR13 is divided into two blank areas VR24 and VR25, and the blank area VR17 is divided into two blank areas VR27 and VR28.

Finally, as shown in FIG. 12D, WPE-enhancing cells Cw12, Cw13, and Cw17 are respectively inserted into the blank areas VR22, VR24, and VR27, respectively, and ordinary filler cells Cof1-Cof6 are disposed into the other blank areas VR1, VR21, VR23, VR25, VR28 and VR6.

In the present embodiment, the blank area optimization and the replacement with the WPE-reduced/enhancing cell are accommodated in communication with the standard cell library. Accordingly, the off-leakage current can be suppressed, to provide a method for speedily and inexpensively designing a semiconductor integrated circuit device excellent in operation speed and driving force.

Although there has been described one embodiment of the present invention, it should be appreciated that the present invention is not limited thereto and its various modifications can be implemented within the scope of the present invention. For example, in the above embodiment an explanation is made for a filler cell, taking a dummy cell constituted with a dummy MISFET as an example. However, the filler cell is never limited to such a dummy cell. For instance, the filler cell includes a cell containing no active areas or dummy gates, besides a cell constituted only by a dummy active area, and a cell constituted only by a dummy gate. Such a cell can be replaced with a cell having a different well structure as a standard cell. Although the above embodiment has been described with reference to a MOSFET that uses a silicon oxide film as an insulating film as an example of the MISFET, the present invention is not limited to it; for example, the present invention can be of course applied to a MOSFET that uses a silicon oxynitride film (SiON) or a hafnium (Hf)-based high-k film as the insulating film.

In addition, it is to be noted that it is not necessary to insert filler cells into all the blank areas.

Although the designing apparatus for a semiconductor integrated circuit device described in the above embodiment includes a plurality of separate components which function independently of each other, the present invention is not limited to it; for example, the present invention can be of course applied to an apparatus in which a general purpose engineering workstation is used to read a recipe file describing a method of designing a the semiconductor integrated circuit mentioned above, and which implements the method.

Furthermore, the blank area may be a filler cell filled with a dummy cell as is shown in FIG. 4 and may be a mere well region that is not filled with even a dummy cell.

What is claimed is:

1. A method of designing a semiconductor integrated circuit device, said method comprising:
arranging standard cells which constitute a MISFET;
analyzing, by using a simulator, an operation timing and/or power consumption of the arranged standard cells and obtaining a result of the analysis;
identifying one of the standard cells that is desired to have improved properties as a cell of interest based on the obtained analysis result;
optimizing an arrangement and/or a shape of blank areas around the cell of interest taking into account an influence of a well proximity effect; and
replacing the blank area and/or the cell of interest with a cell having influence of well proximity effect.

2. The method of claim 1,
wherein the cell having influence of well proximity effect is a well-reduced cell or a well enhancing cell.

3. The method of claim 1,
wherein the replacing is performed in a manner that heights of the identified blank area and/or the cell of interest vary.

4. The method of claim 1,
wherein the replacing is performed in a manner that a conductivity type of the identified blank area is inverted.

5. The method of claim 1, further comprising:
performing automatic interconnection processing after the optimization process is performed; and
further analyzing the operation timing and/or the power consumption between the interconnection processing and the replacing,
wherein the optimizing, the interconnection processing, the further analyzing, and the replacing are repeated until the desired properties are obtained.

6. The method of claim 1, further comprising:
inserting a filler cell into the blank areas after the replacing is performed.

7. The method of claim 5,
wherein the replacing is performed in a manner that widths of the blank areas vary.

8. The method of claim 5,
wherein the replacing is performed in a manner that a relative positional relationship between the blank areas varies.

9. The method of claim 1,
wherein the standard cell is supplied beforehand with information in which a WPE-reduced or enhancing degree is digitized, and
the replacing is performed by utilizing the digitized information.

10. A semiconductor integrated circuit device comprising:
a first well of a first conductivity type semiconductor arranged on a substrate;
a second well of a second conductivity type semiconductor arranged on the substrate adjacent to the first well; and
a third well of the first conductivity type semiconductor arranged on the substrate adjacent to the second well in such a manner that the second well is sandwiched between the first well and the third well,
wherein a MISFET of the first conductivity type is arranged in a first region of the second well, and
assuming that a carrier conduction direction in the MISFET is a first direction and that a direction perpendicular to the first direction is a second direction, a length of the first region in the second well in the second direction is smaller than a length of a second region adjacent to the first region in the first direction and a portion of the third well facing the first region protrudes toward the second well.
